(19) United States
(12) Patent Application Publication
(10) Pub. No.: US 2006/0231844 A1
(43) Pub. Date: Oct. 19, 2006

(54) Organic optoelectronic device

(75) Inventor: Julian Carter, Cambridgeshire (GB)

Correspondence Address: MARSHALL, GERSTEIN & BORUN LLP, 233 S. WACKER DRIVE, SUITE 6300, SEARS TOWER, CHICAGO, IL, 60606, US

(73) Assignee: Cambridge Display Technology Limited

(21) Appl. No.: 10/543,995

(22) PCT Filed: Jan. 29, 2004
(86) PCT No.: PCT/GB04/00380

§ 371 Date: Nov. 21, 2005

(30) Foreign Application Priority Data
Feb. 5, 2003 (GB) 0302550.9

(51) Int. Cl. H01L 33/00

(52) U.S. Cl. 257/79

(57) ABSTRACT

An organic optoelectronic device includes a substrate having an upper surface and a lower surface, at least one organic diode situated on the upper surface of the substrate, the organic diode including, an anode including a material of high work function situated over the upper surface of the substrate, an organic optoelectronic material at least partially overlaying the anode, a cathode including a material of low work function at least partially overlaying the organic optoelectronic material, the cathode being transparent or semi-transparent, wherein the substrate includes at least one connecting via extending through the substrate from the lower surface to the upper surface, the connecting via being suitable for providing an electrical connection between at least one of the anode and/or the cathode of the organic diode and an external circuit. The invention has application in organic light emitting devices and organic photovoltaic devices.

### BACKGROUND OF THE INVENTION

1. Field of the Invention

The present invention relates to an organic optoelectronic device, a display device comprising said organic optoelectronic device and a method of preparing said organic optoelectronic device.

2. Brief Description of the Prior Art

The past decade has seen an increasing amount of research into the use of organic materials in optoelectronic devices, examples of such devices include organic electroluminescent devices, as disclosed in WO90/13148 and organic photovoltaic devices, as disclosed in U.S. Pat. No. 5,670,791. Both organic electroluminescent devices and organic photovoltaic devices are organic diodes comprising a layer of organic material between two electrodes. Organic electroluminescent devices emit light on the passage of a current between the two electrodes. Organic photovoltaic devices generate a current between the two electrodes when light is incident upon the device.

To provide current to drive the organic electroluminescent devices and to enable charge generated on organic photovoltaic devices to be conducted elsewhere it is necessary to provide contacts to the electrodes of the organic diodes. A number of methods have been developed to provide such contacts. The simplest method involves the organic diodes being constructed on a single monolithic substrate such as glass. The lower electrode is situated on the surface of the substrate, a layer of organic material overlies the lower electrode with the upper electrode overlying the layer of organic material. In such a method electrical contacts are made from the electrodes to the edge of the substrate. The disadvantage of this method is that where more complex arrangements of organic diodes are required, as is the case in display applications, the routing of the electrical contacts becomes complex and in particular the attachment of driving electronics to the edge of the substrate may become problematic.

Organic electroluminescent devices have application in high information content displays, such displays require a large number of individually addressable organic electroluminescent devices. To provide a display comprising a multiplicity of organic electroluminescent devices on a single monolithic substrate the devices are generally arranged in the form of a matrix addressed by a series of rows and columns, the rows and columns having an orthogonal arrangement. To drive a particular electroluminescent device a current is driven along the appropriate column with the appropriate row being grounded, such a display is known as a passive matrix display. In such passive matrix displays it is necessary to drive large currents through the electroluminescent devices since the devices are only addressed intermittently, typically each device is addressed with a frequency of 50 Hz. The greater the number of rows and columns in the display the greater the current which must be provided to each electroluminescent device. The need to drive a high current through the electroluminescent devices limits the number of rows and columns which may be used in such a driving scheme since there is an upper current limit which may be passed through the organic electroluminescent device. In order to provide larger displays i.e. both larger area displays and displays having a greater number of pixels, it has been proposed to connect several substrates together to form a tiled display.

As passive matrix displays on a single monolithic substrate require contacts to be made to the edge of the substrate displays of this type are difficult to connect in this manner without the seams between neighbouring substrates being visible in the eventual display. An alternative method for providing displays comprising a multiplicity of organic electroluminescent devices uses a matrix of switches to address the devices. A switch is positioned at each electroluminescent device and the devices can be turned on and off as required without the need to drive a large current through the device. This method, known as active matrix driving, typically uses silicon transistors to provide the switching means. A display will typically be prepared by providing a matrix of switches and other necessary electronic components formed from low temperature polysilicon on a substrate which may be glass, this component is known as the backplane. The organic electroluminescent device will then be deposited on top of the appropriate switch. This method overcomes some of the disadvantages of the above discussed passive matrix method and enables the production of displays having a greater number of pixels and also displays having a large area. But such active matrix displays are very complex and expensive to prepare. Moreover the low yield of the process used to prepare the active matrix backplanes limits the size of displays which can be prepared.

Recently an alternative technology for providing large area displays which does not have the disadvantages inherent in single substrate passive matrix displays or active matrix displays has been developed. This technology uses a ceramic backplane through which electrically conducting vias are provided. The conducting vias provide an electrical connection between the electrodes of the organic diodes and the electronics for driving the display. Since the conducting vias allow connection to be made to the electrodes of the device through the middle of the ceramic backplane rather than at the edges a number of substrates may be seamlessly tiled together to form a large area display and in this way a large area passive matrix display may be formed. FIG. 1 shows a method for the preparation of such a prior art display. FIG. 1a) shows a series of organic electroluminescent devices 100 on a substrate 101, and a ceramic backplane 110 which has a number of vias 111 passing from its upper surface to it's lower surface. The vias are filled with a conducting material 112 in order to render them conductive. The component comprising the organic electroluminescent devices comprises a transparent glass substrate 101, a layer of conducting ITO (indium tin oxide) patterned to form a series of parallel lines 102 which forms the first electrode, in this case the anode. A patterned layer of organic electroluminescent material 103 overlays the ITO. A second electrode, in this case is the cathode 104, is situated over the organic electroluminescent material. The cathode is patterned to form a series of parallel lines orthogonal to the parallel lines of the anode.

FIG. 1b) shows the prior art display device after bonding of the ceramic backplane 110 to the component comprising the electroluminescent devices 100. The ceramic backplane is placed over the component comprising the electroluminescent devices such that the conducting vias lie at least partially above the cathodes of the electroluminescent devices. The conducting vias are then bonded to the upper electrode of the organic electroluminescent device in order to provide an electrical contact from the cathode of the electroluminescent device to the eventual driving circuitry. The conducting vias are generally bonded to the upper electrode of the organic electroluminescent device using a conductive paste such as a silver paste or using a solder 113. The anode 102 may also be connected to external drive circuitry by means of the vias in the ceramic backplate. On passing a current through the electroluminescent devices of the display light is emitted through the glass substrate. An example of such a prior art display device is disclosed in WO99/41732.

Although the above described display devices overcome some of the problems associated with single substrate passive matrix and active matrix displays there are a number of disadvantages associated with these display devices. The displays effectively comprise two substrates, a front transparent glass substrate and a ceramic backplane. This increases the complexity of manufacturing and the thickness and weight of the displays. Further, to provide an electrical connection to the cathode of the electroluminescent device, the vias are filled with conductive paste which is converted to a conductive solid or conductive vias are bonded to the electroluminescent device using a conductive paste or solder. The cathode is exposed to the conductive paste or solder and to solvent vapours generated on converting the paste or solder to a solid. The cathode of the electroluminescent device is generally made from a low work function metal such as calcium. Low work function metals are very sensitive to solvents such as water and so the filling of the vias degrades the material of the cathode. This has a deleterious effect on the display, causing defective pixels (known as black spots) and also reducing the operational lifetime of the display.

There is therefore a need to provide an organic optoelectronic device which combines the advantages associated with the use of substrates comprising conductive vias but without the above mentioned disadvantages.

### SUMMARY OF THE INVENTION

The present inventors have developed an organic optoelectronic device, a display comprising the inventive organic optoelectronic device and a method for preparing the inventive organic optoelectronic devices.

In a first embodiment the present inventors provide an organic optoelectronic device comprising;
a substrate having an upper surface and a lower surface,
at least one organic diode situated on said upper surface of said substrate, said organic diode comprising;
   an anode comprising a material of high work function situated over said upper surface of said substrate,
   an organic optoelectronic material at least partially overlying said anode,
   a cathode comprising a material of low work function at least partially overlying said organic optoelectronic material, said cathode being transparent or semi-transparent,
      characterised in that said substrate comprises at least one connecting via extending through said substrate from said lower surface to said upper surface, said connecting via being suitable for providing an electrical connection between at least one of said anode and/or said cathode of said organic diode and an external circuit.

In the organic optoelectronic devices of the present invention light enters or leaves the device through the cathode which is transparent or semi-transparent. Where the organic optoelectronic device is an organic electroluminescent device this type of device is known as a top emitter. The device architecture provided by the present invention has the advantage over devices of the prior art in that the cathode does not come into contact with the deleterious material used to fill the vias or to bond the conductive vias to the electroluminescent device. In the devices of the prior art emission occurs through the transparent anode so to avoid interfering with the light emission from the display the vias must contact the other side of the diode i.e. the sensitive material of the cathode.

The inventors of the present invention have solved the problem of deterioration of the cathode material and thereby provided an organic optoelectronic device having a longer lifetime and better appearance, in particular with fewer black spots.

The organic optoelectronic device of the present invention has a number of additional advantages. Only a single substrate is used whereas the prior art devices require two substrates i.e. a glass substrate and a ceramic backplane. The use of a single substrate leads to lighter and cheaper displays. A corollary of this is that no registration of two substrates is required in the manufacturing of the device of the present invention. In the devices of the prior art such registration steps increase the complexity of manufacturing and generally require additional features on the substrate to aid registration. The two substrates of the prior art devices serve to protect the organic optoelectronic material and the cathode from the environment. In the devices of the present invention alternative passivating materials or barrier layers may be used, these not only enable the devices to be lighter than those of the prior art but also, where a suitable substrate is used, enable flexible and/or conformable devices to be produced.

The substrate of the present invention may be planar with the upper and lower surfaces being parallel to one another although other arrangements in which the substrate is for example convex or concave are also envisaged.

The connecting vias may be through holes which pass from one surface of the substrate to the other and which are suitable for filling with a conducting material or may be conductive traces or lines such as metal connectors which form an integral part of the substrate. Where the connecting vias are formed as an integral part of the substrate they may provide both a vertical connection between the upper and lower surfaces of the substrate and also a lateral connection between different regions of the substrate.

The organic diodes which form the optoelectronic device of the present invention are preferably organic electroluminescent diodes, also known as organic light emitting diodes, or organic photovoltaic diodes. The organic diodes comprise a layer of organic optoelectronic material situated between two electrodes, namely an anode and a cathode.

In a preferred embodiment said substrate comprises a ceramic or a plastic material.

Suitable ceramics may be selected from high temperature fired ceramics and low temperature co-fired ceramics. Low temperature co-fired ceramics are preferred.

Suitable plastics may be selected from polyvinyl chloride, acrylonitrile butadiene styrene (ABS), aromatic polyimides, polyimides, propylene, polyphenylene sulfide, polycarbonate, acrylics, polyesters, polyethylene terephthalate (PET), polyethylene naphthalate (PEN), polyether sulfone and cyclic olefins. The substrate may be a single monolithic material or may comprise layers of the same or different materials. The substrate may comprise at least a layer of insulating material and at least a layer of conducting material such as a metal.

The organic optoelectronic material of the present invention is an organic material with optical and/or electronic properties. Such properties include electroluminescence, photoluminescence, fluorescence, photoconductivity and conductivity. Electroluminescent materials include light emitting polymers, light emitting dendrimers and so called small molecules such as aluminum trisquinoline.

Photoconductive materials include photoconductive polymers, photoconductive small molecules and fullerenes (C₆₀).

In a preferred embodiment the organic optoelectronic device is an organic electroluminescent device and the organic optoelectronic material comprises a light emitting polymer. Preferred light emitting polymers include polyfluorenes, polybenzothiazoles, polytriarylamines, poly(phenylenevinylenes) and polythiophenes.

In a preferred embodiment the organic optoelectronic device is an organic photovoltaic device and the organic optoelectronic material is an organic photoconductor. To provide an organic photovoltaic device said organic optoelectronic material preferably comprises an organic electron donor and an organic electron acceptor. More preferably at least one of said organic electron donor or said organic electron acceptor comprises a semiconductive polymer. Suitable organic electron donors and acceptors may be selected from the group comprising polyfluorenes, polybenzothiazoles, polytriarylamines, poly(phenylenevinylenes) and polythiophenes. Particularly suitable organic electron acceptors include fullerenes, fullerene derivatives and polymers comprising fullerenes.

The cathode may comprise a single layer of material or multiple layers of materials. The cathode may comprise a metal or an organic material such as a polymer. Preferably the cathode comprises a thin layer of metal of low work function in proximity to the organic optoelectronic material and a further layer of conducting material over said thin layer of metal of low work function. The thin layer of metal provides electron injection into or electron collection from the layer of organic optoelectronic material. The thin layer of metal is preferably selected from the group comprising Ca, Ba, MgAl, LiAl, Mg or MgAg.

The further layer of conducting material is preferably a material which is sufficiently transparent to allow light to enter or exit the layer of optoelectronic material and is also sufficiently conductive to allow charge to be driven into or drawn out of the optoelectronic device. The further layer of conducting material is preferably selected from the group comprising ITO, Al, Au, Ag, IZO (indium zinc oxide) or ZnS.

To improve device efficiency a layer of insulating material may be provided between the layer of organic optoelectronic material and the cathode. In such cases the cathode further comprises a layer of insulating material positioned between said thin layer of metal of low work function and said organic optoelectronic material. The insulating material being sufficiently thin to allow the passage of charge carriers between the low work function electrode and the organic optoelectronic material. The thin layer of insulating material preferably has a thickness of between 1 nm and 10 nm. The insulating material is preferably selected from the group comprising alkali or alkaline earth metal fluorides and most preferably is selected from amongst LiF, BaF₂ and NaF.

The anode of the organic optoelectronic device is preferably selected from the group comprising ITO, Au, Pt.

The anode preferably comprises a material having a work function of greater than 4.3 eV and the cathode preferably comprises a material having a work function of less than 3.5 eV.

To improve the lifetime of the organic optoelectronic device the device is protected from contact with atmospheric oxygen and moisture preferably by providing a layer of passivating material over said cathode. The passivating material forms a barrier preventing the ingress of oxygen and water vapour.

In a preferred embodiment said organic optoelectronic device comprises a plurality of connecting vias extending through said substrate from said lower surface to said upper surface.

It is preferred that the connecting via or a at least some of the plurality of connecting vias are at least partially filled with an electrically conducting material. The electrically conducting material may be selected from the group comprising highly conductive metals such as gold, aluminum or platinum or conductive pastes such as conductive silver or graphite pastes.

Preferably the organic optoelectronic device comprises a plurality of organic diodes, such an arrangement enables the formation of a high information content display.

In a further embodiment the present invention provides a display device comprising;
an organic optoelectronic device comprising;
a substrate having an upper surface and a lower surface,
at least one organic diode situated on said upper surface of said substrate,
said organic diode comprising;
   an anode comprising a material of high work function situated over said upper surface of said substrate,
   an organic optoelectronic material at least partially overlying said anode,
   a cathode comprising a material of low work function at least partially overlying said organic optoelectronic material, said cathode being transparent or semi-transparent,
      characterised in that said substrate comprises at least one connecting via or a plurality of connecting vias extending through said substrate from said lower surface to said upper surface, said connecting via or said connecting vias being at least partially filled with an electrically conducting material,
      further comprising drive circuitry, said drive circuitry electrically connected to at least one of said anode or said cathode through said connecting via or said connecting vias.

Preferably the drive circuitry is electrically connected to both said anode and said cathode through said connecting via or said connecting vias. Preferably the display device comprises a plurality of organic diodes.

The present invention also provides a further method of preparing an organic optoelectronic device according to the invention comprising;
providing a substrate having an upper surface and a lower surface, said substrate further comprising at least one connecting via or a plurality of connecting vias extending through said substrate from said lower surface to said upper surface,
said connecting via or said connecting vias being at least partially filled with an electrically conducting material suitable for enabling an electrical contact to be made between said upper surface of said substrate and said lower surface of said substrate,
providing a layer of material of high work function over said upper surface of said substrate,
providing a layer of an organic optoelectronic material over said layer of material of high work function,
providing a layer of transparent or semi-transparent material of low work function over said layer of organic optoelectronic material.

Preferably the layer of material of high work function is patterned. The layer of high work function material may be patterned by additive techniques such as printing or by subtractive techniques such as photolithography. The layer of high work function material is preferably patterned to form a series of parallel lines.

Following deposition of the layer of high work function material it is preferred to deposit a layer of insulating material over the layer of material of high work function and pattern said layer of insulating material. This layer of insulating material allows further device layers to be patterned. The layer of insulating material may be patterned by photolithography and is such case is preferably a photopatternable polymer. The layer of insulating material is preferably patterned to form a series of parallel lines which are orthogonal to the parallel lines of the patterned material of low work function. Insulating material patterned in this manner is known in the art as banks. Altematvely the insulating material may be patterned to form a series of wells. Wells are recesses in the insulating material where material has been removed revealing the underlying layer of material of low work function. In a more preferred embodiment a first layer of insulating material is deposited to form a series of wells and a second layer of insulating material is deposit over said first layer to form a series of banks.

Preferably a patterned layer of organic optoelectronic material is provided. The patterned layer of optoelectronic material may be provided by subtractive or additive techniques and preferably is provided by a selective printing technique such as flexographic printing, gravure printing or ink-jet printing. Most preferably the patterned layer of optoelectronic material is provided by ink-jet printing.

Preferably said low work function material is deposited by means of vapour deposition. It is preferred to provide a layer of passivating material over the layer of material of low work function. The layer of passivating material may be provided by means of vapour deposition such as PVD or PECVD.

In the method of preparing an organic optoelectronic device according to the present invention it is preferred that the layer of material of low work function which forms the cathode of the device is deposited such that it is in electrical contact with at least one of the connecting vias, this enables both the cathode and the anode to be electrically contacted through the vias in the substrate. In one embodiment of the present invention prior to providing a layer of material of low work function the organic optoelectronic material is removed from above some of the connecting vias allowing the layer of material of low work function to be deposited over and in electrical contact with said connecting via or said connecting vias. The organic optoelectronic material may be removed, for example, by laser ablation. In an alternative embodiment the organic optoelectronic material is selectively deposited over the substrate such that said organic optoelectronic material is not deposited over all of said connecting vias such that in said step of providing a layer of material of low work function said layer of material of low work function is deposited over and in electrical contact with said connecting via or said connecting vias. Methods of selective printing are preferred for the selective deposition of the organic optoelectronic material, ink jet printing is particularly preferred.

### DETAILED DESCRIPTION OF THE INVENTION

### BRIEF DESCRIPTION OF THE DRAWINGS

FIG. 1 illustrates a prior art organic electroluminescent device on a ceramic substrate.

FIG. 2 illustrates an organic optoelectronic device according to the present invention.

FIG. 3 shows a plurality of organic diodes on a substrate according to the present invention.

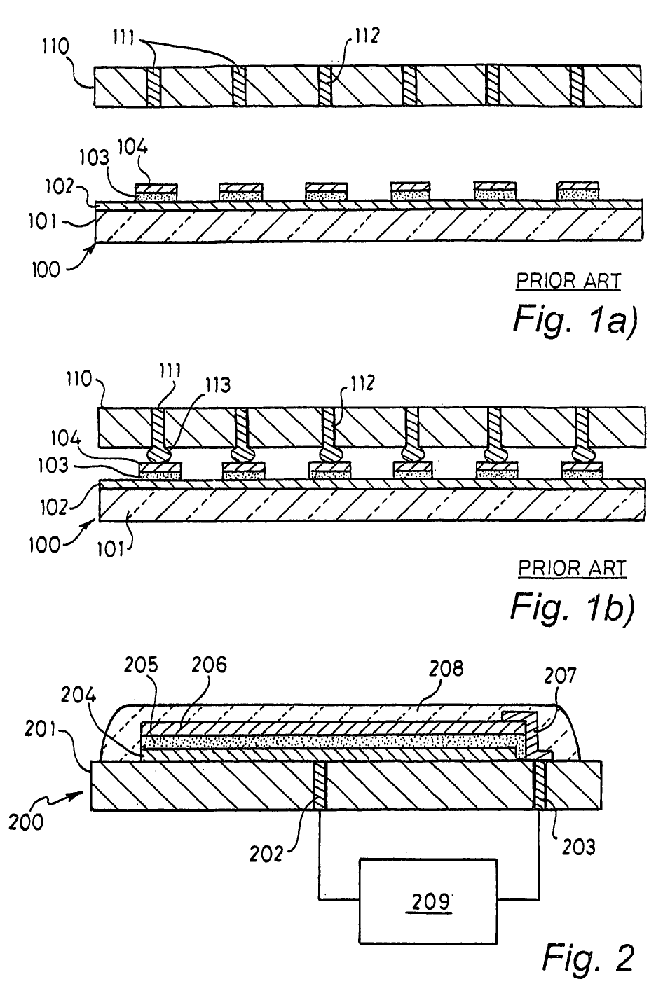

### DESCRIPTION OF PREFERRED EMBODIMENTS

An optoelectronic device according to the present invention is shown in FIG. 2. The optoelectronic device 200 comprises a substrate 201 through which connecting vias 202 203 have been provided. Over the upper surface of the substrate 201 and in electrical contact with via 202 lies a layer of anode material 204. The anode is in turn covered by a layer of organic optoelectronic material 205 over which lies the cathode 206. An electrical connector 207 serves to connect the cathode 206 to via 203. The organic diode is encapsulated with a layer of passivating material 208 and the anode and cathode are connected to driving circuitry 209.

The substrate may be rigid or flexible and is generally opaque although in some cases a transparent or semi-transparent substrate may be used.

The substrate typically comprises a material selected from the group comprising ceramics and plastics. The term ceramic is taken to include both ceramics and glasses. Ceramics include high temperature fired ceramics such as alumina, lower melting devitrifying glasses such as are disclosed in U.S. Pat. No. 5,216,207 and low-temperature co-fired ceramic on metal composites as disclosed in GB2263253. The substrate may be a composite material such as a glass/plastic composite as disclosed in EP0949850.

Suitable plastics include polyvinyl chloride, acrylonitrile butadiene styrene (ABS), aromatic polyimides, polyimides, propylene, polyphenylene sulfide, polycarbonate, acrylics, polyesters, polyethylene terephthalate (PET), polyethylene naphthalate (PEN), polyether sulfone and cyclic olefins.

The connecting vias may be through holes passing from one surface of the substrate to the other which are filled with conductive material or they may be formed as an integral part of the substrate, for example as metal traces running from one surface of the substrate to the other. Suitable materials for filling the connecting vias include inks or pastes formed from conductive metal particles such as copper, silver and gold combined with an organic resin and a suitable solvent. Where the connecting vias are formed as an integral part of the substrate they are formed from high conductivity materials such as platinum, copper, aluminum or gold, although molybdenum, titanium, tungsten, conductive polymers or conductive oxides may also be used. The connecting vias will generally have a diameter of between 5 and 100 microns and preferably have a diameter of between 5 and 10 microns.

On the upper surface on the substrate is situated the anode 204 of the organic optoelectronic device. The anode comprises a layer of conductive material of high work function, generally having a work function greater than 4.3 eV. Suitable materials include ITO, tin oxide, aluminum or indium doped zinc oxide, magnesium-indium oxide, cadmium tin-oxide, gold, silver, nickel, palladium and platinum. In cases where the substrate is transparent and it is desired that light enter or leave the device through the substrate the anode material may be transparent.

An optional layer of hole-transporting material may be situated over the anode. The hole-transport material serves to increase charge conduction through the device. The preferred hole-transport material used in the art is a conductive organic polymer such as polystyrene sulfonic acid doped polyethylene dioxythiophene (PEDOT:PSS) as disclosed in WO98/05187, although other hole transporting materials such as doped polyaniline or TPD (N,N′-diphenyl-N,N′-bis(3-methylphenyl)[1,1′-biphenyl]-4,4′-diamine) may also be used.

The nature of the organic optoelectronic material to a large extent determines the function of the device. The preferred organic optoelectronic devices of the present invention are organic electroluminescent devices and organic photovoltaic devices. In organic electroluminescent devices the optoelectronic material comprises an organic electroluminescent material. Suitable organic electroluminescent materials include polymeric light emitting materials, such as disclosed in Bernius et al Advanced Materials, 2000, 12, 1737, low molecular weight light emitting materials such aluminum trisquinoline, as disclosed in U.S. Pat. No. 5,294,869, light emitting dendrimers as disclosed in WO99/21935 or phosphorescent materials as disclosed in WO00/70655. The light emitting material may comprise a blend of a light emitting material and a fluorescent dye or may comprise a layered structure of a light emitting material and a fluorescent dye. Due to their processibility soluble light emitting materials are preferred, in particular soluble light-emitting polymers. Light emitting polymers include polyfluorene, polybenzothiazole, polytriarylamine, poly(phenylenevinylene) and polythiophene. Preferred light emitting polymers include homopolymers and copolymers of 9,9-di-n-octylfluorene (F8), N,N-bis(phenyl)-4-sec-butylphenylamine (TFB) and benzothiadiazole (BT). A layer of electron transporting or hole blocking material may be positioned over the layer of light emitting material if required to improve device efficiency.

In organic photovoltaic devices the optoelectronic material comprises an organic photoconductive material. Organic heterojunction photovoltaic devices are currently one of the most efficient types of organic photovoltaic devices. Organic heterojunction photovoltaic devices comprise an organic electron donor and an organic electron acceptor, such devices are disclosed in U.S. Pat. No. 5,331,183. A variety of structures of the organic photovoltaic devices are possible. The electron donor and electron acceptor may comprise polymers or low molecular weight compounds. The electron donor and acceptor may be present as two separate layers, as disclosed in WO99/49525, or as a blend or so called bulk heterojunction, as disclosed in U.S. Pat. No. 5,670,791. The electron donor and acceptor may be selected from perylene derivatives such as N,N′-diphenylglyoxaline-3,4,9,10-perylene tetracarboxylic acid diacidamide, fullerenes (C₆₀), fullerene derivatives and fullerene containing polymers and semiconducting organic polymers such as polyfluorenes, polybenzothiazoles, polytriarylamines, poly(phenylenevinylenes), polyphenylenes, polythiophenes, polypyrroles, polyacetylenes, polyisonaphthalenes and polyquinolines. Preferred polymers include MEH-PPV (poly(2-methoxy, 5-(2′-ethyl)hexyloxy-p-phenylenevinylene)), MEH-CN-PPV (poly(2,5-bis(nitrilemethyl)-1-methoxy-4-(2′-ethyl-hexyloxy) benzene-co-2,5-dialdehyde-I-methoxy4-(2′-ethylhexyloxy)benzene)) and CN-PPV cyano substituted PPV, polyalkylthiophenes, such as poly(3-hexylthiophene), POPT poly(3(4-octylphenyl)thiophene) and poly(3-dodecylthiophene), polyfluorenes, such as poly(2,7-(9,9-di-n-octylfluorene), poly(2,7-(9,9-di-n-octylfluorene)-benzothiadiazole) and poly(2,7-(9,9-di-n-octylfluorene)-(4,7-di-2-thienyl-(benzothiazole)). Typical device structures include a blend of N,N′-diphenylglyoxaline-3,4,9,10-perylene tetracarboxylic acid diacidamide and poly(3-dodecylthiophene), a layered structure comprising a layer of MEH-PPV and a layer of C₆₀, a blend of MEH-PPV and C₆₀, a layered structure comprising a layer of MEH-CN-PPV and a layer of POPT, a blend comprising MEH-PPV and CN-PPV and a blend comprising poly(3-hexylthiophene) and poly(2,7-(9,9-di-n-octylfluorene)-(4,7-di-2-thienyl-(benzothiazole)).

An advantage of the present invention is that the connecting vias allow electrical contact to be made to the anode and cathode of the diode through the substrate rather than around the sides of the substrate. Forming the connection between anode and connecting via is uncomplicated as the anode is deposited directly over the substrate and the connecting vias and can therefore be deposited in electrical contact with the connecting vias. To connect the cathode to the connecting vias requires that any material which has been deposited in an earlier fabrication step such as any light emitting polymer or hole transporting material, should be removed from above the connecting vias with which it is intended that the cathode make contact. This organic material may be removed by laser ablation or any other suitable technique. Alternatively the organic materials of device may be deposited by a selective deposition technique whereby the organic material is not deposited over the connecting vias with which it is intended that the cathode make contact. Suitable selective deposition techniques include selective printing techniques with inkjet printing being a particularly suitable technique.

The cathode 206 overlies the layer of organic optoelectronic material. In the device of the present invention the cathode is transparent or semi-transparent. A transparent cathode will have greater than 80% light transmission, a semi-transparent cathode will have a light transmission of 20 to 80%. As explained above the use of the transparent cathode in the present invention allows the optoelectronic device to emit or receive light through the cathode rather than through the anode as occurs in prior art devices. This architecture allows the cathode to be deposited as the last step in the formation of the device with the cathode being deposited such that it is already in contact with the connecting via or such that it may be connected by an additional connector such as feature 207 in FIG. 2, this additional connector may be deposited using a vapour deposition process. As described above the substrate and the other layers of the device are prepared such that the cathode or the additional connector form an electrical connection with the appropriate connecting vias on deposition. Since there is no requirement for the connecting vias to be filled when in contact with the cathode or for the cathode to be bonded to the conductive vias using a conductive paste or solder, the cathode is not exposed to deleterious material.

The transparent cathode is typically formed from a thin layer of metal having a low work function situated next to the organic optoelectronic material. This layer provides for the injection of electrons into the organic material or, in the case of an organic photovoltaic device, for the collection of electrons. A further layer of conductive material overlies the thin metal layer, this is generally a thicker layer of a less conductive, transparent material. Metals suitable for the thin layer of low work function material include Ca, Ba, Mg, MgAl, LiAl, MgAg. This layer has a thickness of between 1 nm and 30 nm, preferably 5 nm and 20 nm. Materials suitable for the further layer of conducting material include ITO, Al, Ag, IZO, ZnS. This layer has a thickness of between 1 nm and 20 nm, preferably 1 nm to 10 nm.

A thin layer of insulating material is often provided between the organic layer and the thin layer of low work function material. This insulating material serves to improve device efficiency by enhancing the electron transport across the metal/organic interface. The insulating material generally has a thickness of between 1 nm and 10 nm. Suitable materials for the insulating material include alkali or alkaline earth metal halides or oxides such as LIF, NaF, MgF₂, BaF₂, LI₂O, BaO.

Suitable structures for the transparent cathode include a cathode comprising;
a thin layer of insulating material, a layer of metal of low work function and a further layer of metal, for example;
BaF₂/Ca/Au
LiF/Ca/Au
Li₂O/Ag/ITO
a thin layer of insulating material, a layer of metal and a further layer of a metal containing material, for example;
LiF/Al/MgO
LiF/Al/Ag
a thin layer of insulating material and a further layer of conducting material, for example;
LiF/ITO
LiF/Al
Li₂O/ZnS

A thin layer of metal and an overlying layer of transparent, wide bandgap semiconductor, for example;
Ca/ZnSe
MgAl/ITO

A carbide, nitride or boride of an early transition metal, lanthanide or alkaline earth metal, for example;
CaB₆, LaB₆, TiC, HfC, TaC, ZrN, HfN

The cathode may be deposited such that it is directly connected to a connecting via or, as shown in FIG. 2, an electrical connector 207 may be deposited over the cathode to connect the cathode to the connecting via. The electrical connector may be deposited by vapour deposition through a suitable mask.

Following deposition of the cathode a layer of protective material may be deposited. This layer provides mechanical protection for the organic optoelectronic device. SiO is a suitable protective material and is typically deposited by vapour deposition or sputtering to a thickness of between 1 and 10 nm.

To provide environmental protection the device is then encapsulated. Where the substrate is a ceramic encapsulation may take the form of a glass sheet which is glass bonded to the substrate with a low temperature frit material. To avoid the necessity of using a glass sheet to encapsulate the device a layer of passivating material may be deposited over the device. Suitable barrier layers comprise a layered structure of alternating polymer and ceramic films and may be deposited by PECVD as disclosed in WO0036665 and U.S. Pat. No. 5,686,360. Such a barrier layer is shown as feature 208 in FIG. 2. Alternatively the device may be encapsulated by enclosure in a metal can.

The substrate of the present invention allows electrical connection to be made to both anode and cathode through the connecting vias. In order to provide a driving signal to the display, or in the case of a photovoltaic device to draw current from the photovoltaic diodes, suitable electronics will be attached to the connecting vias, this is shown as driving circuitry 209. Driving circuitry for a passive matrix display will comprise a current source connected to the column electrodes of the display, which are typically formed by the cathodes of the organic electroluminescent devices and a row selector connected to the row electrodes of the display, which are typically formed by the anodes of the organic electroluminescent devices, a central processor will provide a timing signal to the row selector and a data signal to the appropriate column electrodes. The driver may be in the form of a circuit chip attached to the lower surface of the substrate, where the substrate is a plastic the circuit chips may be deposited using fluidic self-assembly as disclosed in WO00/46854.

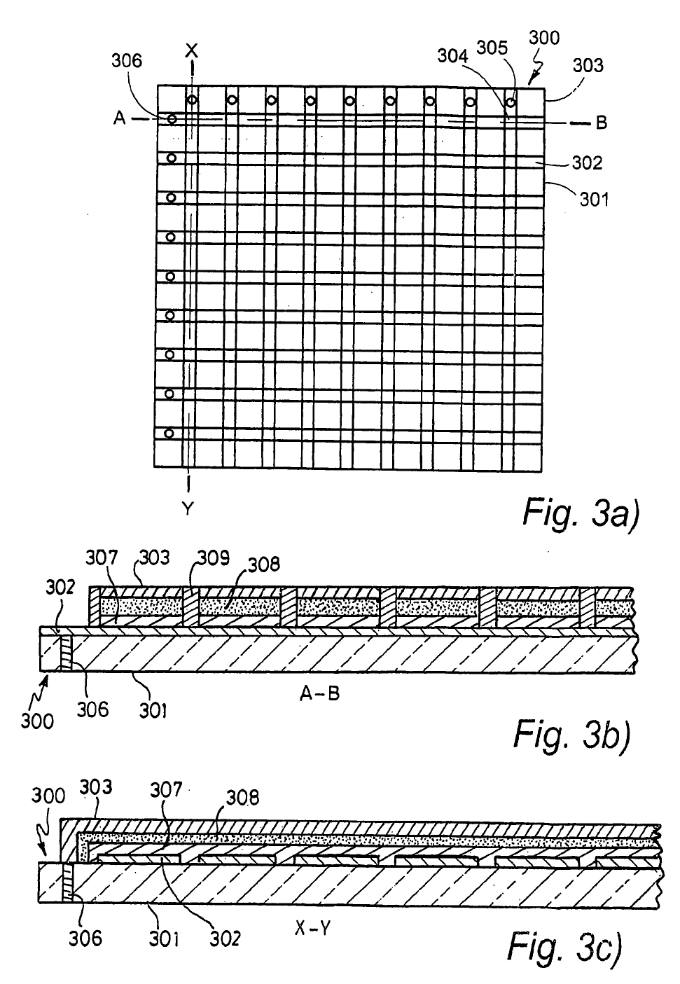

FIG. 3a) shows an implementation of the present invention in a passive matrix display device 300. A series of parallel lines of ITO or another suitable anode material 302 are situated upon a ceramic substrate 301. An organic optoelectronic material is deposited over the ITO to define the light emitting pixels of the display 304. A cathode 303 is formed as a series of parallel lines orthogonal to the lines of ITO. The ITO contacts connecting vias 306 running along the edge of the display. The cathode contacts connecting vias 305 running along the top of the display. Driver electronics are connected to the connecting vias on the underside, or lower surface, of the substrate.

FIG. 3b) shows a cross section along line A-B through the display of FIG. 3a). The display comprises a glass substrate 301, a layer of ITO 302, a series of banks 309 which enable the organic optoelectronic material to be deposited as a solution (for clarity banks 309 are not shown in FIG. 3a)). A layer of hole transporting material 307, such as PEDOT:PSS, lies over the ITO, a layer of light emitting polymer 308 lies over the hole transporting material (for clarity the hole transporting layer 307 and the light emitting layer 308 are not shown in FIG. 3a)). A cathode 303 is deposited over the layer of light emitting polymer. Connecting via 306 serves to connect the ITO anode to external driver circuitry.

FIG. 3c) shows a cross section along line X-Y through the display of FIG. 3a). The display comprises a glass substrate 301, a layer of ITO 302, a layer of hole transporting material 307, such as PEDOT:PSS, lies over the ITO, a layer of light emitting polymer 308 lies over the hole transporting material. A cathode 303 is deposited over the layer of light emitting polymer. Connecting via 305 serves to connect the cathode to external driver circuitry.

Clearly it is not essential for the connecting vias to be situated at the periphery of the substrate as shown in FIG. 3 and the vias may be positioned in the centre of the display.

A significant advantage of the present invention is that the substrates can be tiled together to produce larger area displays. Since electrical connection is made to the back of the substrate, rather than to the side, several substrates can be seamlessly tiled together with driving electronics being connected to the back, or lower surface, of the substrate. A tiled display may be built up from a number of substrates each comprising a discrete passively addressed display, in this way large area passive matrix driven displays may be formed without the need to drive excessively large currents through the diodes of the display. Using the present invention it is possible to make a large area or high resolution display without the very high cost of using active matrix semiconductor based backplanes.

The following is a description of a preferred method of preparing an organic electroluminescent device comprising soluble light emitting polymers according to the present invention. This method would also be applicable to the preparation of a variety of other organic optoelectronic devices such as organic photovoltaic devices.

The substrate referred to in the following description is a low-temperature co-fired ceramic on metal composite such as that described in WO02/23579. Clearly other substrates, such as plastic substrates, could also be used with appropriate modifications.

The ceramic substrate 301 is coated with a layer of ITO 302 to form the anode of the eventual electroluminescent device. ITO may be deposited by sputtering or any other suitable method known to those in the art. The ITO layer on the substrate is then patterned using photolithography. The layer of ITO is coated with a photoresist, patterned, for example using a UV source and a photomask, and developed using the appropriate developing solution. Exposed ITO is then removed by chemical etching, leaving a patterned layer of ITO. Typically the ITO is patterned to form a series of parallel stripes.

A layer of photopattemable, insulating polymer such as a polyimide or a fluorinated photoresist is then deposited onto the patterned ITO. The photopatternable polymer may be deposited by spin-coating, doctor blade coating or any other suitable technique. The photopattemable polymer is patterned using conventional photolithographic techniques, for example after deposition the photopattemable polymer is dried, exposed to UV light through a mask, soft baked, developed using, for example, tetramethylammonium hydroxide, rinsed and hard baked. Preferred patterns of the insulating polymer are those that define banks, which are one dimensional patterns, for example parallel stripes, or wells, which are two dimensional patterns of recesses in the insulating polymer. Banks typically have a height of 0.5 to 10 microns and a width of 10 to 100 microns and define channels containing regions of ITO having a width of 10 to 500 microns. Wells may have a diameter of 10 to 100 microns. FIG. 3b) shows an electroluminescent device having a series of banks 309 between areas of light emission. For the further processing of the device it is preferred that the banks should have a negative wall profile. Banks having a negative wall profile are narrower in proximity to the substrate, typically a bank will have an upper width of around 40 microns and a lower width of around 20 to 38 microns. Techniques for obtaining banks with a negative wall profile are known in the art and, in the case of a negative photoresist, involve underexposing and then overdeveloping the photoresist. The provision of banks with a negative wall profile is beneficial for the further processing of the substrate, in particular banks having a negative wall profile aid the patterned deposition of the metallic cathode. EP0969701 discloses the use of banks having a negative wall profile in the deposition of a cathode in an organic electroluminescent device. The choice of patterning the insulating polymer to form banks or wells is determined by the nature of the eventual light emitting device. If it is desired that the device emit light of a single colour, i.e. a monochrome device, it is sufficient to pattern the substrates with banks. If it is desired that the device emit in more than one colour, in particular in red, green and blue, the insulating polymer will generally be patterned to form wells, thus enabling light emitting materials of different colours to be deposited separately, with an additional layer of banks to facilitate cathode deposition.

The substrate, layers of photopatternable polymer and exposed ITO may be further surface treated for example using oxygen plasma or ultraviolet light. This serves to alter the surface energies of the materials of the substrate making them more suitable for the deposition of the device layers. Surface treatment is particularly desirable when further materials are to be deposited by solution processing techniques.

A layer of hole-transporting material, 307 FIG. 3b), is then deposited upon the patterned ITO. The preferred hole-transport material used in the art is a conductive organic polymer such as polystyrene sulfonic acid doped polyethylene dioxythiophene (PEDOT:PSS) as disclosed in WO98/05187, although other hole transporting materials such as doped polyaniline may also be used. The hole-transporting material may be deposited by ink jet printing. PEDOT:PSS may be ink-jet printed as an aqueous solution. The aqueous solution typically has a concentration of 1 to 10% of hole-transporting material. After deposition the aqueous solution is allowed to evaporate leaving a layer of hole-transporting material of thickness 10 nm to 200 nm. The PEDOT:PSS is ink-jet printed so that the connecting vias which are intended to form a contact with the cathode are not covered by PEDOT:PSS.

Following deposition of the hole transporting layer, a layer of light emitting material, 308 FIG. 3b) is deposited into selected wells on the substrate. The light emitting polymer is deposited using ink-jet printing. Conjugated polymers such as polyfluorene and poly(phenylene vinylene) may be ink-jet printed from solutions of aromatic solvents such as toluene, xylene, trimethylbenzene etc. The light-emitting polymer may be ink-jet printed from a solution of concentration 0.5 to 10%, the thickness of the deposited layer of light-emitting polymer is generally 10 nm to 300 nm. As above the light emitting polymer is deposited by ink-jet printing such that the connecting vias which are intended to form a contact with the cathode are not covered by light emitting polymer.

In cases where the PEDOT:PSS and the light emitting polymer, or other appropriate device materials, are deposited by non-selective techniques, such as spin-coating or doctor blade it may be necessary to remove the material from above the connecting vias to which the cathode will connect. Laser ablation is a suitable technique for the removal of excess material.

A cathode material 303 is then deposited over the light emitting material. The cathode material is deposited by means of vapour deposition. Where appropriate multilayer cathodes may be deposited, for example cathodes comprising a layer of alkali or alkaline earth metal fluorides and layers of metals as discussed above. A particularly preferred cathode comprises LIF/Ca/Al, with a layer of LiF of thickness from 1 to 10 nm, a layer of Ca of thickness of 1 to 25 mm and a layer of Al of thickness 10 to 500 mm.

The device is then encapsulated, this may be carried out by means of enclosing the device in a metal can or glass cover to protect the device from the environment, an oxygen or moisture absorbent may be including within the metal can or glass cover, such a technique is disclosed in U.S. Pat. No. 6,080,031. Alternatively devices may be encapsulated by laminating an impermeable composite material over the device as is disclosed in WO00/36661.

The present invention has particular application in the field of organic light emitting devices where it enables the production of large area displays. The present invention also has application in the field of organic photovoltaic devices. Organic photovoltaic devices are generally formed on glass substrates, the use of more robust ceramic or plastic substrates as in the present invention greatly increases the fields of application of organic photovoltaic devices such as for the roofing or exterior cladding of buildings. The present invention also allows organic photovoltaic devices to be seamlessly tiled together, enabling greater active surface coverage and allowing the devices to be series connected to increase the voltage generation.

No doubt the teaching herein makes many other embodiments of, and effective alternatives to, the present invention apparent to a person skilled in the art. The present invention is not limited to the specific embodiments described herein but encompasses modifications which would be apparent to those skilled in the art and lying with the spirit and scope of the attached claims.

1. An organic optoelectronic device comprising;
a substrate having an upper surface and a lower surface, and
at least one organic diode situated on said upper surface of said substrate, said organic diode comprising;
an anode comprising a material of high work function situated over said upper surface of said substrate,
an organic optoelectronic material at least partially overlying said anode,
a cathode comprising a material of low work function at least partially overlying said organic optoelectronic material, said cathode being transparent or semi-transparent,
wherein said substrate comprises at least one connecting via extending through said substrate from said lower surface to said upper surface, said connecting via being suitable for providing an electrical connection between at least one of said anode and said cathode of said organic diode and an external circuit.

2. An organic optoelectronic device according to claim 1 wherein said substrate comprises a ceramic.

3. An organic optoelectronic device according to claim 1 wherein said substrate comprises a plastic.

4. An organic optoelectronic device according to claim 1 wherein said organic optoelectronic material comprises light emitting polymer.

5. An organic optoelectronic device according to claim 1 wherein said organic optoelectronic material comprises an organic electron donor and an organic electron acceptor.

6. An organic optoelectronic device according to claim 5 wherein at least one of said organic electron donor or said organic electron acceptor comprises a semiconductive polymer.

7. An organic optoelectronic device according to claim 1 wherein said cathode comprises a thin layer of metal of low work function in proximity to said organic optoelectronic material and a further layer of conducting material over said thin layer of metal of low work function.

8. An organic optoelectronic device according to claim 7 wherein said thin layer of metal comprises a metal selected from the group consisting of Ca, Ba, MgAl, LiAl, Mg, and MgAg.

9. An organic optoelectronic device according to claim 7 wherein said cathode further comprises a layer of insulating material positioned between said thin layer of metal of low work function and said organic optoelectronic material, said insulating material being sufficiently thin to allow the passage of charge carriers between the low work function electrode and the organic optoelectronic material.

10. An organic optoelectronic device according to claim 7 wherein said further layer of conducting material is selected from the group consisting of ITO, Al, Au, Ag, IZO, and ZnS.

11. An organic optoelectronic device according to claim 1 wherein said anode is selected from the group consisting of ITO, Au, and Pt.

12. An organic optoelectronic device according to claim 1 wherein said device further comprises a layer of passivating material over said cathode.

13. An organic optoelectronic. device according to claim 1 wherein said device comprises a plurality of connecting vias extending through said substrate from said lower surface to said upper surface.

14. An organic optoelectronic device according to claim 1 or claim 13 wherein said connecting via is at least partially filled with an electrically conducting material.

15. An organic optoelectronic device according to claim 14 wherein said electrically conducting material is selected from the group consisting of highly conductive metals and conductive pastes.

16. An organic optoelectronic device according to claim 1 comprising a plurality of organic diodes.

17. A display device comprising;
an organic optoelectronic device comprising;
a substrate having an upper surface and a lower surface, and,
at least one organic diode situated on said upper surface of said substrate, said organic diode comprising;
an anode comprising a material of high work function situated over said upper surface of said substrate,
an organic optoelectronic material at least partially overlying said anode,
a cathode comprising a material of low work function at least partially overlying said organic optoelectronic material, said cathode.being transparent or semi-transparent,
wherein said substrate comprises at least one connecting via extending through said substrate from said lower surface to said upper surface, at least one said connecting via being at least partially filled with an electrically conducting material,
said display device further comprising drive circuitry, said drive circuitry electrically connected to at least one of said anode or said cathode through said connecting via or vias.

18. A display device according to claim 17 wherein said drive circuitry is electrically connected to both said anode and said cathode through said connecting via or vias.

19. A method of preparing an organic optoelectronic device according to claim 1 comprising;
providing a substrate having an upper surface and a lower surface, said substrate further comprising at least one connecting via extending through said substrate from said lower surface to said upper surface,
said connecting via or vias being at least partially filled with an electrically conducting material suitable for enabling an electrical contact to be made between said upper surface of said substrate and said lower surface of said substrate,
providing a layer of material of high work function over said upper surface of said substrate,
providing a layer of an organic optoelectronic material over said layer of material of high work function, and
providing a layer of transparent or semi-transparent material of low work function over said layer of organic optoelectronic material.

20. A method of preparing an organic optoelectronic device according to claim 19 wherein prior to providing said layer of material of low work function said organic optoelectronic material is removed from above at least one of said connecting vias allowing said layer of material of low work function to be deposited over and in electrical contact with said connecting via or said connecting vias.

21. A method of preparing an organic optoelectronic device according to claim 19 wherein said organic optoelectronic material is provided by means of a selective deposition technique such that said organic optoelectronic material is not deposited over all of said connecting via or vias such that in said step of providing a layer of material of low work function said layer of material of low work function is deposited over and in electrical contact with said connecting via or said connecting vias.

22. An organic optoelectronic device according to claim 15 wherein said electrically conducting material is selected from the group consisting of gold, platinum, aluminum, silver pastes, and graphite pastes.

23. An organic optoelectronic device according to claim 13 wherein at least one of said plurality of connecting vias is at least partially filled with an electronically conducting material.

24. An organic optoelectronic device according to claim 23 wherein said electrically conducting material is selected from the group consisting of highly conductive metals and conductive pastes.

25. An organic optoelectronic device according to claim 24 wherein said electrically conducting material is selected from the group consisting of gold, platinum, aluminum, silver pastes, and graphite pastes.
